(19) United States
(12) Patent Application Publication
(10) Pub. No.: US 2010/0163941 A1
(43) Pub. Date: Jul. 1, 2010

(54) IMAGE SENSOR AND METHOD FOR MANUFACTURING THE SAME

(76) Inventor: Seung-Man Jung, Hwaseong-si (KR)

Correspondence Address: SHERR & VAUGHN, PLLC, 620 HERNDON PARKWAY, SUITE 320, HERNDON, VA, 20170, US

(21) Appl. No.: 12/648,203

(22) Filed: Dec. 28, 2009

(30) Foreign Application Priority Data
Dec. 30, 2008 (KR) 10-2008-0137469

(51) Int. Cl. H01L 27/146; H01L 31/18

(52) U.S. Cl. 257/292; 438/69; 257/E27.133

(57) ABSTRACT

An image sensor and a method for manufacturing the same that includes readout circuitry, an electrical junction region, an interconnection, an image sensing device, and an infrared filter. The readout circuitry and the electrical junction region are formed in a first substrate and are electrically connected to each other. The interconnection is formed over the electrical junction region and the image sensing device is formed over the interconnection. The infrared filter is formed on the image sensing device and includes a plurality of thin films.

The present application claims priority under 35 U.S.C. §119 to Korean Patent Application No. 10-2008-0137469 (filed Dec. 30, 2008), which is hereby incorporated by reference in its entirety.

### BACKGROUND

Image sensors are semiconductor devices which convert optical images into electrical signals. Such image sensors can typically be classified as either Charge Coupled Device (CCD) image sensors or Complementary Metal Oxide Silicon (CMOS) image sensors (CIS).

During the fabrication of image sensors, a photodiode may be formed in a substrate using ion implantation. As the size of a photodiode is reduced for the purpose of increasing the number of pixels without increasing overall chip size, the area of a light receiving portion is also reduced, resulting in a reduction in image quality. Moreover, since a stack height does not reduce as much as the reduction in the area of the light receiving portion, the number of photons incident to the light receiving portion is also being reduced due to diffraction of light called airy disk.

As an alternative to overcome this limitation, an attempt of forming a photodiode using amorphous silicon (Si), or forming a readout circuitry in a silicon (Si) substrate using a method such as wafer-to-wafer bonding, and forming a photodiode on and/or over the readout circuitry has been made (referred to as a “three-dimensional (3D) image sensor”). The photodiode is connected to the readout circuitry through a metal interconnection.

Since an image sensor converts even infrared rays invisible to human eyes into photoelectrons, the image sensor makes an image different from an image viewed by human eyes, for example, look reddish.

To overcome this limitation, an infrared filter is being used to remove infrared rays when a module of an image sensor is manufactured. However, when this method is applied to an image sensor (such as a 3D image sensor) in which a light-receiving unit is formed on and/or over an interconnection structure, the manufacturing cost of an image sensor module increases significantly. Furthermore, since the infrared filter is mounted into the module, the size of the module increases to make miniaturization difficult. There is an additional limitation in that a charge sharing phenomenon may occur because both the source and the drain of the transfer transistor are heavily doped with N-type impurities. The charge sharing phenomenon may cause reduction of the sensitivity of an output image and generation of image error. Moreover, photocharges can not smoothly move between a photodiode and a readout circuitry, causing generation of a dark current and reduction of saturation and sensitivity.

### SUMMARY

Embodiments relate to an image sensor and a method for manufacturing the same which reduces the overall manufacturing costs of a module while also achieving miniaturization by providing an infrared filter on and/or over the image sensor in which a light-receiving unit is formed on and/or over an interconnection structure.

Embodiments relate to an image sensor and a method for manufacturing the same which increases a fill factor without a charge sharing phenomenon.

Embodiments relate to an image sensor and a method for manufacturing the same which minimizes a dark current source and inhibits saturation reduction and sensitivity degradation by forming a smooth transfer path of photocharges between a photodiode and a readout circuit.

In accordance with embodiments, an image sensor can include at least one of the following: a readout circuitry formed in a first substrate; an electrical junction region formed in the first substrate, the electrical junction region being electrically connected to the readout circuitry; an interconnection formed on and/or over the electrical junction region; an image sensing device formed on and/or over the interconnection; and an infrared filter formed on and/or over the image sensing device, the infrared filter having a plurality of thin films.

In accordance with embodiments, a method for manufacturing an image sensor can include at least one of the following: forming a readout circuitry in a first substrate; forming an electrical junction region in the first substrate, the electrical junction region being electrically connected to the readout circuitry; forming an interconnection on and/or over the electrical junction region; forming an image sensing device on and/or over the interconnection; and forming an infrared filter on and/or over the image sensing device, the infrared filter including a plurality of thin films.

### DRAWINGS

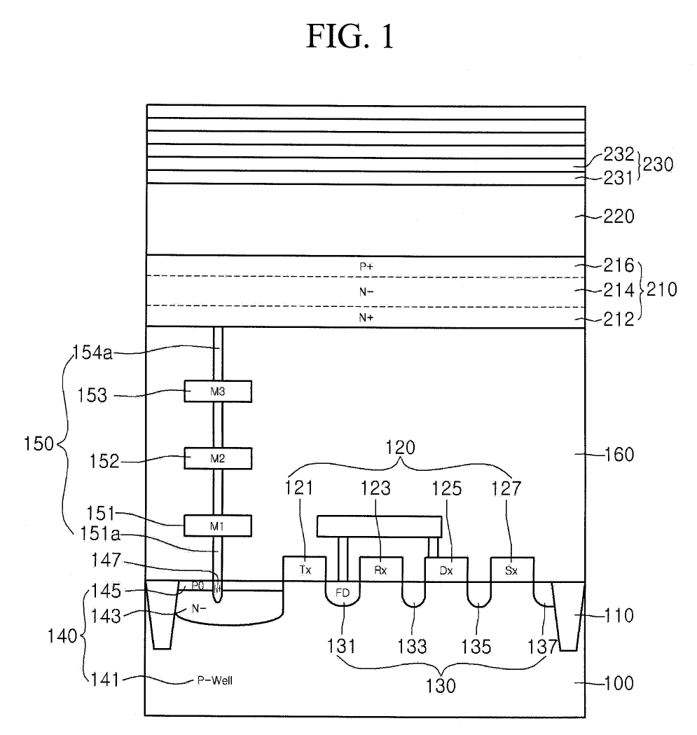

Example FIGS. 1 to 8 illustrate an image sensor and a method for manufacturing an image sensor, in accordance with embodiments.

### DESCRIPTION

Hereinafter, an image sensor and a method for manufacturing the same in accordance with embodiments will be described with reference to the accompanying drawings.

In the description of embodiments, it will be understood that when a layer (or film) is referred to as being “on” another layer or substrate, it can be directly on another layer or substrate, or intervening layers may also be present. Further, it will be understood that when a layer is referred to as being “under” another layer, it can be directly under another layer, and one or more intervening layers may also be present. In addition, it will also be understood that when a layer is referred to as being “between” two layers, it can be the only layer between the two layers, or one or more intervening layers may also be present.

Example FIG. 1 is a cross-section view of an image sensor in accordance with embodiments.

As illustrated in example FIG. 1, an image sensor in accordance with embodiments can include readout circuitry 120 in first substrate 100, electrical junction region 140 in first substrate 100, electrical junction region 140 being electrically connected to readout circuitry 120, interconnection 150 on and/or over the electrical junction region 140; image sensing device 210 on and/or over interconnection 150; and infrared filter 230 on and/or over image sensing device 210, infrared filter 230 having a plurality of thin films.

Image sensing device 210 may be a photodiode, but, without being limited thereto, may be a photogate, or a combination of a photodiode and a photogate. In accordance with embodiments, although it is described as an example that a photodiode is formed in a crystalline semiconductor layer, the photodiode may be formed in an amorphous semiconductor layer.

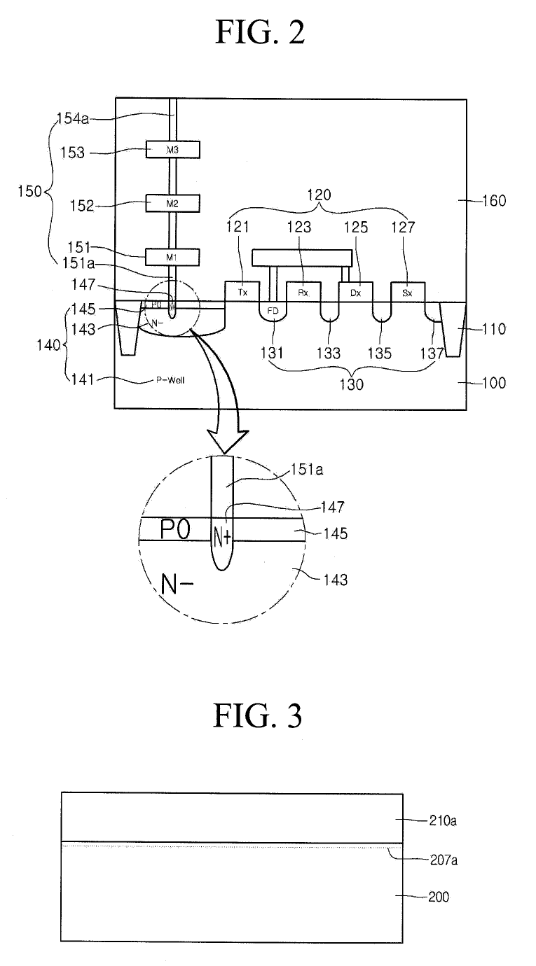

Hereinafter, a method for manufacturing an image sensor in accordance with embodiments will be described with reference to example FIGS. 2 to 7.

As illustrated in example FIG. 2, first substrate 100 where interconnection 150 and readout circuitry 120 are formed is prepared. For example, device isolation layer 110 is formed in second conductive-type first substrate 100 to define active regions. Readout circuitry 120 including transistors is formed in the active region. For example, readout circuitry 120 may include transfer transistor (Tx) 121, reset transistor (Rx) 123, drive transistor (Dx) 125, and select transistor (Sx) 127. An ion implantation region 130 including floating diffusion region 131 and first source/drain region 133, second source/drain region 135 and third source/drain region 137 for the respective transistors may be formed. In accordance with embodiments, a noise removing circuit may be added to enhance overall sensitivity.

The forming of readout circuitry 120 in first substrate 100 may include forming electrical junction region 140 in first substrate 100, and forming first conductive-type connection 147 connected to interconnection 150 at an upper portion of electrical junction region 140. For example, electrical junction region 140 may be a P-N junction 140, but is not limited thereto. Electrical junction region 140 may include first conductive-type ion implantation layer 143 formed on and/or over second conductive-type well 141 or a second conductive-type epitaxial layer, and second conductive-type ion implantation layer 145 formed on and/or over first conductive-type ion implantation layer 143. P-N junction 140 may be a P0 145/N-143/P-141 junction, but is not limited thereto. First substrate 100 may be conducted with a second conductive-type, but is not limited thereto.

In accordance with embodiments, the device may be designed to have a potential difference between the source and drain of a transfer transistor (Tx), thus enabling the full dumping of photocharges. Accordingly, photocharges generated in a photodiode may be dumped to a floating diffusion region, thereby increasing sensitivity of an output image. Meaning, electrical junction region 140 may be formed in first substrate 100 including readout circuitry 120 to provide a potential difference between the source and drain of transfer transistor (Tx) 121, thereby enabling the full dumping of photocharges. Unlike a case where a photodiode is merely connected using an N+ junction, embodiments can avoid saturation reduction and sensitivity degradation.

Thereafter, first conductive-type connection 147 is formed between the photodiode and the readout circuitry to create a smooth transfer path of photocharges, thereby making it possible to minimize a dark current source and inhibit saturation reduction and sensitivity degradation. For this, an n+ doping region as first conductive-type connection 147 for an ohmic contact may be formed on and/or over the surface of P0/N-/P-junction 140. N+ region 147 may penetrate through P0 145 to contact N-143.

On the other hand, the width of first conductive type connection 147 may be minimized to inhibit first conductive type connection 147 from becoming a leakage source. For this, a plug implant may be performed after etching first metal contact 151a, but is not limited thereto. As another example, an ion implantation pattern may be formed, and then first conductive-type connection 147 may be formed using the ion implantation pattern as an ion implantation mask. Meaning, the reasons why an N+ doping is locally performed only at a contact formation region as described in embodiments are to minimize a dark signal and facilitate formation of an ohmic contact. If the entire Tx source region is doped with N+ type, a dark signal may increase due to an Si surface dangling bond.

Interlayer dielectric 160 may then be formed on and/or over first substrate 100. Interconnection 150 may be then formed extending through interlayer dielectric 160. Interconnection 150 may include first metal contact 151a, first metal 151, second metal 152, third metal 153, fourth metal contact 154a, but embodiments are not limited thereto.

As illustrated in example FIG. 3, crystalline semiconductor layer 210a may be formed on and/or over second substrate 200. In accordance with embodiments, photodiode 210 is formed in crystalline semiconductor layer 210a. Thus, embodiments may adopt a 3D image sensor in which an image sensing device is located on and/or over a readout circuitry, thereby increasing a fill factor. Also, in accordance with embodiments, the image sensing device may be formed in crystalline semiconductor layer 210a, thereby inhibiting defects in the image sensing device. For example, crystalline semiconductor layer 210a may be formed on and/or over second substrate 200 through an epitaxial growth process. Thereafter, hydrogen ions may be implanted into a boundary region between second substrate 200 and crystalline semiconductor layer 210a to form hydrogen ion implantation layer 207a. The implantation of the hydrogen ions may be performed after an ion implantation for forming photodiode 210.

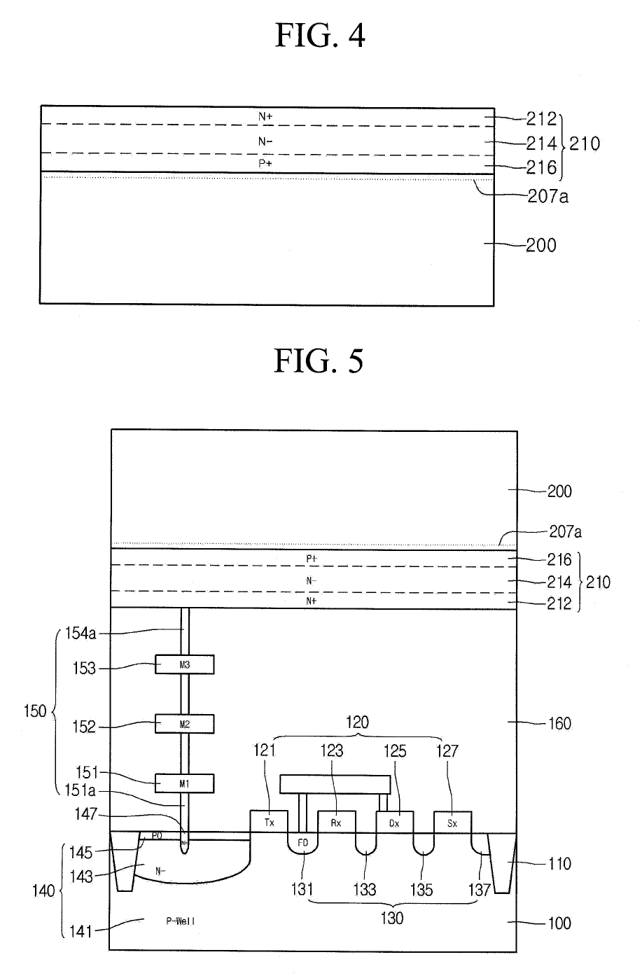

As illustrated in example FIG. 4, photodiode 210 may be formed through an ion implantation into crystalline semiconductor layer 210a. Second conductive-type conductive layer 216 may be formed at a lower portion of crystalline semiconductor layer 210a. Meaning, ions may be implanted on and/or over the entire surface of second substrate 200 through a blanket without a mask, forming high-concentration P-type conductive layer 216. Second conductive-type conductive layer 216 may be formed at a junction depth of less than about 0.5 μm.

First conductive type conductive layer 214 may then be formed on and/or over second conductive-type conductive layer 216. For example, ions may be implanted over the entire surface of second substrate 200 through a blanket without a mask, thereby forming low-concentration N-type conductor layer 214. Low-concentration first conductive-type conductive layer 214 may be formed at a junction depth in a range of between about 1.0 μm to about 2.0 μm.

In accordance with embodiments, first conductive-type conductive layer 214 may be formed to have a thickness greater than that of second conductive-type conductive layer 216, thereby increasing a charge storing capacity. Meaning, N-layer 214 may be formed to have a greater thickness, thereby increasing capacity that can contain photoelectrons.

Thereafter, high-concentration first conductive-type conductive layer 212 may then be formed on and/or over first conductive-type conductive layer 214. For example, high-concentration first conductive-type conductive layer 212 may be formed at a junction depth in a range between about 0.05 μm to about 0.2 μm. Ions may be further implanted on and/or over the entire surface of second substrate 200 through a blanket without a mask, thereby forming high-concentration N+ type conductive layer 212, which can contribute to an ohmic contact.

As illustrated in example FIG. 5, first substrate 100 and second substrate 200 may then be bonded to each other such that photodiode 210 contacts interconnection 150. In this case, the surface energy of bonded surfaces may be increased by plasma activation before first substrate 100 and second substrate 200 are bonded to each other. One of an insulating layer or a metal layer may be interposed in a bonding interface to enhance the bonding strength.

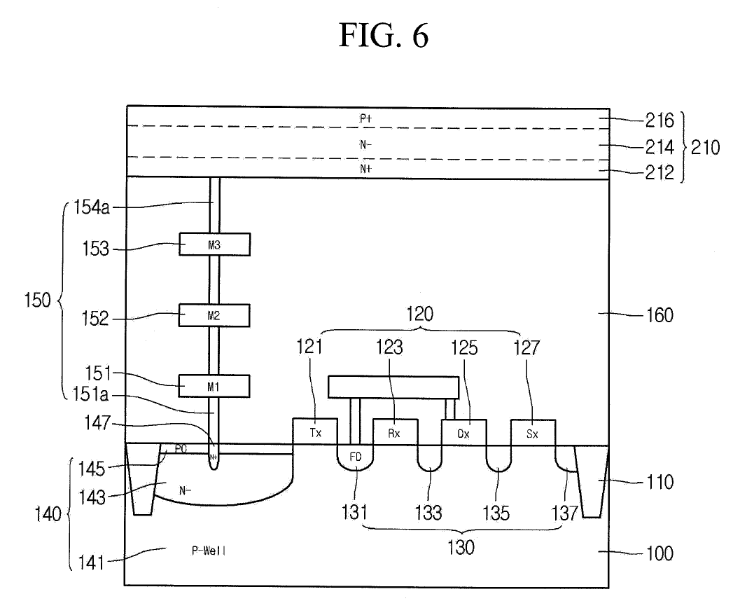

As illustrated in example FIG. 6, hydrogen ion implantation layer 207a may be changed into a hydrogen gas layer through a heat treatment of second substrate 200. Thereafter, a portion of second substrate 200 may be removed at the hydrogen gas layer using a blade, leaving photodiode 210 exposed. Next, a process for separating photodiode 210 into pixels may be performed. For example, ions may be implanted into a boundary between pixels, or a device isolation layer may be formed.

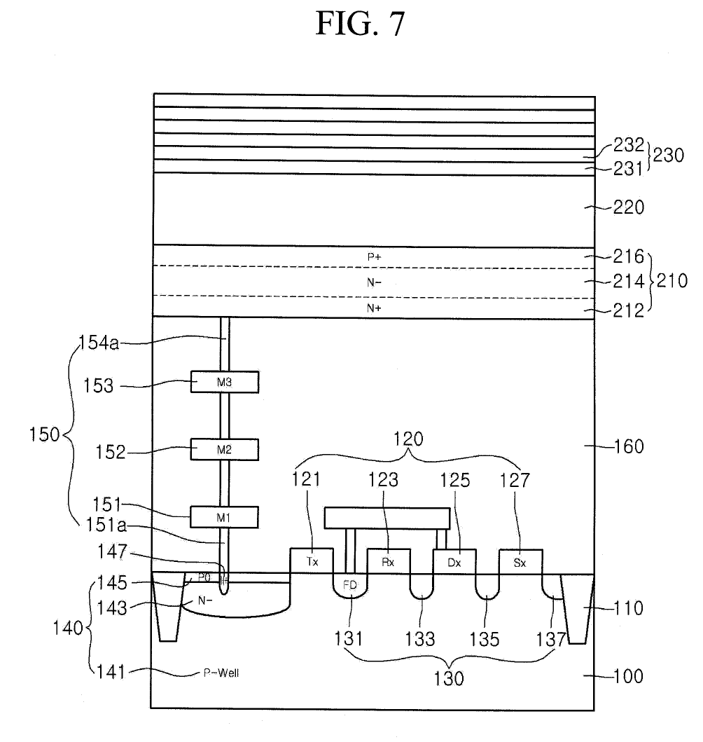

As illustrated in example FIG. 7, color filter 220 and infrared filter 230 may then be sequentially formed on and/or over image sensing device 210. The forming of infrared filter 230 may include forming first thin film 231 having first refractive index on the color filter 220 and forming second film 232 having second refractive index on and/or over first film 231. For example, thin films having different refractive indexes may be alternately formed in a staked structure of about three to about ten layers to form infrared filter 230. Infrared filter 230 may be formed through a process for forming a semiconductor thin film at a temperature of less than about 350° C. to protect a PR structure such as color filter 220 under infrared filter 230.

First film 231 applied to infrared filter 230 may be formed using a film that has a relatively smaller refractive index in a range between about 1.3 to about 1.7. For example, first film 230 may be composed of silicon oxide (SiO2), but is not limited thereto. On the other hand, second film 232 may be formed using a film that has a relatively greater refractive index in a range of between about 1.8 to about 2.2. For example, second film 232 may be composed of silicon nitride (SiN), but is not limited thereto. First film 231 of infrared filter 230 may be formed to have a thickness in a range between about 300 Å to about 1,500 Å, and second film 232 may be formed to have a thickness in a range between about 100 Å to about 1,000 Å. In this case, the thicknesses of the first thin film 231 and second thin film 232 may be selectively combined to optimize the overall thickness of infrared filter 230. For example, first thin film 231 may be composed of SiO₂ having a thickness in a range between about 1,200 Å to about 1,400 Å and second thin film 232 may be composed of SiN having a thickness in a range between about 700 Å to about 800 Å.

In accordance with embodiments, an infrared filter is manufactured during the manufacturing of a wafer of an image sensor in which a light-receiving unit is formed on and/or over an interconnection structure. Accordingly, cost for mounting a separate infrared filter in a module can be saved. Also, since the infrared filter is excluded from the module, miniaturization of the module can be achieved. Furthermore, the device may be designed to have a potential difference between the source and drain of a transfer transistor (Tx), thus enabling the full dumping of photocharges. A charge connection is formed between the photodiode and the readout circuitry to create a smooth transfer path of photocharges, thereby making it possible to minimize a dark current source and inhibit saturation reduction and sensitivity degradation.

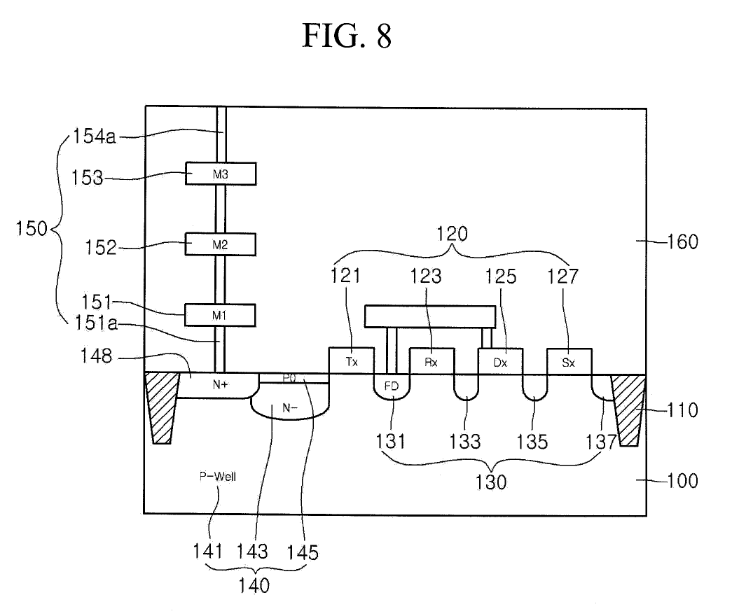

Example FIG. 8 is a cross-sectional view of an image sensor in accordance with embodiments, and is a detailed view of a first substrate where interconnection 150 are formed. Embodiments illustrated in example FIG. 8 may adopt the technical features of those illustrated in example FIGS. 2-7. Hereinafter, detailed descriptions will be made based on features discriminated from those illustrated in example FIGS. 2-7.

As illustrated in example FIG. 8, in accordance with embodiments, N+ connection region 148 may be formed at P0/N-/P-junction 140 for an ohmic contact. In this case, a leakage source may occur during a process for forming N+ connection region 148 and M1C contact 151a. This is because an electric field (EF) may be generated over the surface of a silicon substrate due to operation while a reverse bias is applied to P0/N-/P-junction 140. A crystal defect that may be generated during a process for forming a contact in the electric field may become a leakage source. Also, when N+ connection region 148 is formed on and/or over the surface of P0/N-/P-junction 140, an electric field may be additionally generated due to N+/P0 junction 148/145. This electric field may also become a leakage source. Therefore, embodiments propose a layout in which first contact plug 151a is formed in an active region including N+ connection region 148 without being doped with a P0 layer, and is connected to N-junction 143. In accordance with embodiments, an electric field is not generated on and/or over the surface of the silicon substrate, thereby contributing to reduction of a dark current in a 3D-integrated CIS.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus comprising:
a readout circuitry formed in a first substrate;
an electrical junction region formed in the first substrate and electrically connected to the readout circuitry;
an interconnection formed over the electrical junction region;
an image sensing device formed over the interconnection; and
an infrared filter comprising a plurality of thin films formed over the image sensing device.

2. The apparatus of claim 1, wherein the infrared filter comprises:
a first thin film having a first refractive index; and
a second thin film formed over the first thin film, the second thin film having a second refractive index greater than the first refractive index.

3. The apparatus of claim 2, wherein the first refractive index ranges from about 1.3 to about 1.7 and the second refractive index ranges from about 1.8 to about 2.2.

4. The apparatus of claim 2, wherein the first thin film and the second thin film are alternately stacked in about three to about ten layers.

5. The apparatus of claim 2, wherein the first thin film has a thickness in a range between about 300 Å to about 1,500 Å, and the second thin film has a thickness in a range between about 100 Å to about 1,000 Å.

6. The apparatus of claim 2, wherein the first thin film comprises silicon oxide and the second thin film comprises silicon nitride.

7. The apparatus of claim 1, wherein the readout circuitry comprises a transistor having a potential difference between a source and drain thereof.

8. The apparatus of claim 7, wherein the transistor comprises a transfer transistor, and an ion implantation concentration of the source of the transistor is less than that of a floating diffusion region.

9. The apparatus of claim 1, further comprising a first conductive-type connection formed between the electrical and the interconnection and electrically connected to the interconnection at an upper portion of the electrical junction region.

10. The apparatus of claim 1, further comprising a first conductive-type connection formed between the electrical and the interconnection and electrically connected to the interconnection at one side of the electrical junction region.

11-20. (canceled)

21. A method comprising:
forming a readout circuitry in a first substrate;
forming an electrical junction region in the first substrate and electrically connected to the readout circuitry;
forming an interconnection over the electrical junction region;
forming an image sensing device over the interconnection; and then
forming an infrared filter comprising a plurality of thin films over the image sensing device.

22. The method of claim 21, wherein forming the infrared filter comprises:
forming a first thin film having a first refractive index; and then
forming a second thin film over the first thin film, the second thin film having a second refractive index greater than the first refractive index.

23. The method of claim 22, wherein the first refractive index ranges from about 1.3 to about 1.7 and the second refractive index ranges from about 1.8 to about 2.2.

24. The method of claim 22, wherein forming the infrared filter comprises alternately forming the first thin film and the second thin film in a stacked structure of about three to about ten layers.

25. The method of claim 22, wherein the first thin film has a thickness n a range between about 300 Å to about 1,500 Å and the second thin film has a thickness in a range between about 100 Å to about 1,000 Å.

26. The method of claim 22, wherein the forming of the infrared filter is performed at a temperature of less than about 350° C.

27. The method of claim 21, wherein the readout circuitry comprises a transistor having a potential difference between the source and drain thereof.

28. The method of claim 27, wherein the transistor comprises a transfer transistor, and an ion implantation concentration of the source of the transistor is less than that of a floating diffusion region.

29. The method of claim 21, further comprising forming a first conductive-type connection between the electrical junction region and the interconnection, the first conductive-type connection being electrically connected to the interconnection at an upper portion of the electrical junction region.

30. The method of claim 21, further comprising forming a first conductive-type connection between the electrical junction region and the interconnection, the first conductive-type connection being electrically connected to the interconnection at one side of the electrical junction region.
